(19) United States
(12) Patent Application Publication
(10) Pub. No.: US 2024/0305249 A1
(43) Pub. Date: Sep. 12, 2024

(54) AMPLIFIER CIRCUITRY WITH SUPPLY COMPENSATION

(71) Applicant: Cirrus Logic International Semiconductor Ltd., Edinburgh (GB)

(72) Inventors: John L. MELANSON, Austin, TX (US); Thomas H. HOFF, Austin, TX (US)

(73) Assignee: Cirrus Logic International Semiconductor Ltd., Edinburgh (GB)

(21) Appl. No.: 18/181,975

(22) Filed: Mar. 10, 2023

(51) Int. Cl. H03F 1/30; H03F 3/213; H03F 3/217

(52) U.S. Cl. CPC H03F 1/30; H03F 3/213; H03F 3/2171; H03F 2200/129; H03F 2200/171

(57) ABSTRACT

Amplifier circuitry comprising: output stage circuitry configured to modulate a power supply voltage, based on a drive signal received at an input of the output stage circuitry, to generate an amplifier output signal; a feedback path coupled to an output of the output stage circuitry and configured to generate a feedback signal based on the amplifier output signal; loop filter circuitry configured to receive an input signal based on the feedback signal and to output a digital loop filter output signal; divider circuitry configured to divide the digital loop filter output signal by the power supply voltage to generate a divided digital output signal; and encoder circuitry configured to generate the drive signal based on the divided digital output signal.

### FIELD OF THE INVENTION

The present disclosure relates to amplifier circuitry.

### BACKGROUND

Many amplifier circuits operate by modulating a supply voltage according to an input signal to be amplified to generate an amplified output signal. For example, in a class D amplifier circuit, switches (e.g. MOSFET devices) of an output stage are controlled, based on the input signal, to couple an output node to either a first supply rail (e.g. a positive supply voltage rail) or a second supply rail (e.g. a ground or other reference voltage rail), to generate an output signal comprising a sequence of pulses which can be used (either directly or after a suitable low-pass filter stage) to drive a load such as a speaker or other output transducer.

Because such amplifier circuits modulate the supply voltage, any variation in the supply voltage (for example caused by supply voltage ripple or longer-term changes such as a reduction in the magnitude of the positive supply voltage caused by discharging of a battery that provides the positive supply voltage, or connection of a load to the positive power supply rail) will give rise to a corresponding change in a gain of the output stage of the amplifier circuit. This change in gain can lead to distortion or steady state gain error in the output signal, if left uncompensated.

Amplifier circuits typically include a loop filter to regulate errors in the response of the amplifier circuit due to variations in supply voltage, temperature or other non-idealities. In such circuits a feedback path is provided for feeding back a portion of the output signal, which is subtracted from the input signal to generate an error signal. This error signal is received by the loop filter, which typically integrates the error signal to generate a filtered output signal. The loop filter of an amplifier circuit may also produce an additional signal to compensate for variations in the output stage gain due to variations in the supply voltage, thus reducing distortion and/or other errors in the output signal.

### SUMMARY

According to a first aspect, the invention provides amplifier circuitry comprising:
output stage circuitry configured to modulate a power supply voltage, based on a drive signal received at an input of the output stage circuitry, to generate an amplifier output signal;
a feedback path coupled to an output of the output stage circuitry and configured to generate a feedback signal based on the amplifier output signal;
loop filter circuitry configured to receive an input signal based on the feedback signal and to output a digital loop filter output signal;
divider circuitry configured to divide the digital loop filter output signal by the power supply voltage to generate a divided digital output signal; and
encoder circuitry configured to generate the drive signal based on the divided digital output signal.

The output stage circuitry may comprise Class D output stage circuitry.

The loop filter circuitry may comprise analog to digital converter (ADC) circuitry.

The loop filter circuitry may comprise analog loop filter circuitry.

The analog loop filter circuitry may comprise one or more analog integrators.

The loop filter circuitry may comprise digital loop filter circuitry.

The digital loop filter circuitry may comprise digital integrator circuitry.

The encoder circuitry may comprise pulse width modulation (PWM) encoder circuitry.

The input signal may comprise an error signal indicative of a difference between an amplifier input signal and the amplifier output signal.

The amplifier circuitry may further comprise subtractor circuitry configured to subtract the amplifier output signal from the amplifier input signal.

The amplifier input signal may be an audio signal.

According to a second aspect, the invention provides amplifier circuitry comprising:
output stage circuitry configured to modulate a supply voltage to generate an amplifier output signal;
hybrid loop filter circuitry; and
compensation circuitry,
wherein the compensation circuitry is configured to generate a drive signal for driving the output stage circuitry based on an output signal of the hybrid loop filter circuitry,
wherein the drive signal is configured to compensate for a supply-dependent gain variation of the output stage circuitry.

According to a third aspect, the invention provides supply compensation circuitry comprising:
analog to digital converter (ADC) circuitry configured to generate a digital signal indicative of a supply voltage;
digital divider circuitry configured to divide an input signal by the digital signal indicative of the supply voltage to generate a divided digital signal; and
digital encoder circuitry configured to generate an encoded output signal based on the divided digital signal.

According to a fourth aspect, the invention provides an integrated circuit comprising amplifier circuitry according to the first or second aspect, or supply compensation circuitry according to the third aspect.

According to a fifth aspect, the invention provides a host device comprising amplifier circuitry to the first or second aspect, or supply compensation circuitry according to the third aspect.

The host device may comprise, for example a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

### BRIEF DESCRIPTION OF THE DRAWINGS

Embodiments of the invention will now be described, strictly by way of example only, with reference to the accompanying drawings, of which:

FIG. 1 is a schematic representation of amplifier circuitry with a loop filter arrangement;

FIG. 2 is a schematic representation of amplifier circuitry with power supply compensation; and

FIG. 3 is a schematic representation of amplifier circuitry according to the present disclosure, having a hybrid loop filter arrangement and power supply compensation circuitry.

### DETAILED DESCRIPTION

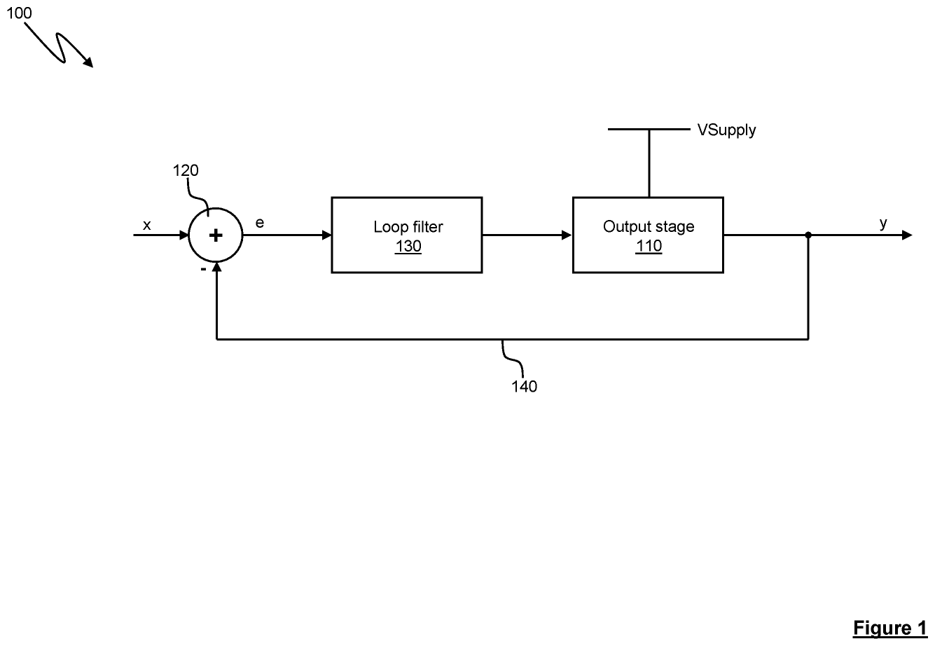

FIG. 1 is a schematic representation of amplifier circuitry that includes a loop filter arrangement. The amplifier circuitry, shown generally at 100 in FIG. 1, includes analog output stage circuitry 110, a subtractor circuitry 120 and analog loop filter circuitry 130.

The analog output stage circuitry 110 may be, for example, Class D output stage circuitry, and is configured to receive an input signal from the loop filter circuitry 130. The analog output stage circuitry 110 is configured to generate an output signal y by modulating a supply voltage VSupply based on the input signal, as described above.

The output of the analog output stage circuitry 110 is coupled, via an analog feedback path 140, to a first input of the subtractor circuitry 120. A second input of the subtractor circuitry 120 receives an input signal x, to be amplified by the amplifier circuitry 100. The input signal x may be, for example, a digital or analog audio signal. The subtractor circuitry 120 is configured to subtract the output signal y from the input signal x to generate an error signal e, which is output to the analog loop filter circuitry 130.

The analog loop filter circuitry 130 is configured to filter the error signal e and to output a filtered version of the error signal e to the analog output stage circuitry 110, which, as noted above, is configured to generate the output signal y by modulating the supply voltage VSupply based on the filtered version of the error signal e output by the analog loop filter circuitry 130. The analog loop filter circuitry 130 may comprise one or more analog integrators, for example

As noted above, in amplifier circuitry of the kind shown generally at 100 in FIG. 1, any variation in the supply voltage VSupply will give rise to a corresponding change in the gain of the output stage circuitry 110. Thus, in the example amplifier circuitry 100 of FIG. 1, the gain G of the analog output stage circuitry 110 can be expressed as G=k*VSupply, where k is a constant.

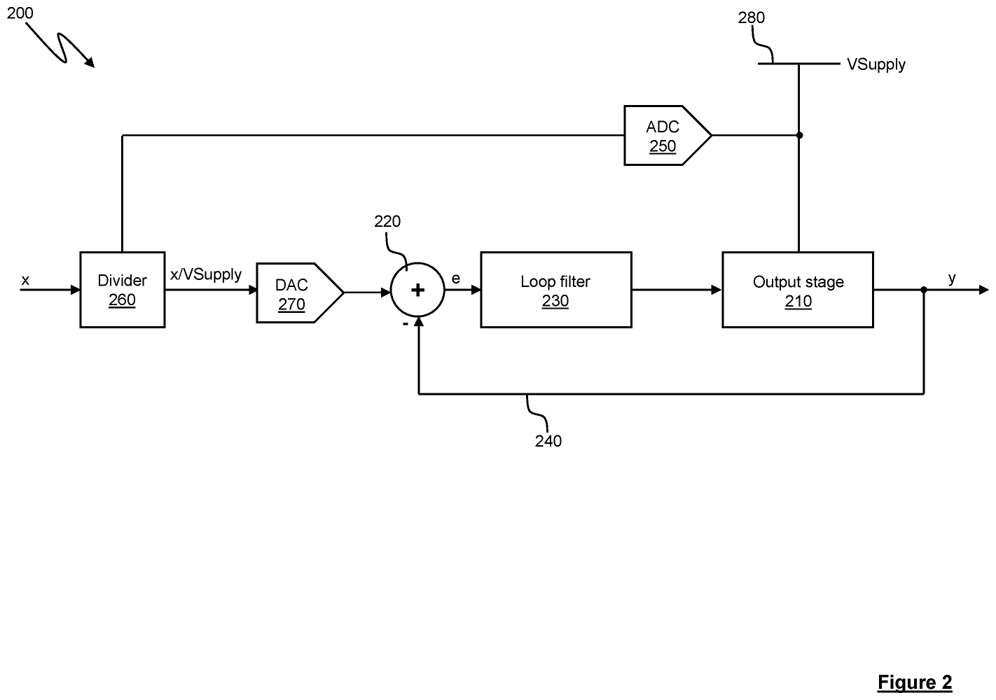

FIG. 2 is a schematic representation of amplifier circuitry that implements power supply compensation to compensate for supply-dependent variations in the gain of an output stage.

The amplifier circuitry, shown generally at 200 in FIG. 2, is similar in some ways to the amplifier circuitry 100 of FIG. 1, in that it includes analog output stage circuitry 210 (which may be, for example, Class D output stage), a subtractor circuitry 220, analog loop filter circuitry 230 and an analog feedback path 240 between an output of the output stage circuitry 210 and a first input of the subtractor circuitry 220.

The amplifier circuitry 200 further includes analog to digital converter (ADC) circuitry 250, digital divider circuitry 260 and digital to analog converter (DAC) circuitry 270.

An input of the ADC circuitry 250 is coupled to a positive power supply voltage rail 280 which provides a supply voltage VSupply to the analog output stage circuitry 210. An output of the ADC circuitry 250 is coupled to a first input of the digital divider circuitry 260, such that the ADC circuitry 250 supplies a digital signal representing a magnitude of the supply voltage VSupply to the digital divider circuitry 260.

A second input of the digital divider circuitry 260 is coupled to an input node of the amplifier circuitry 200, so as to receive an input signal x, which may be, for example, a digital or analog audio signal. The digital divider circuitry 260 is configured to divide the input signal x by the digital representation of the supply voltage VSupply, and to output a digital signal x/VSupply to an input of the DAC circuitry 270. The DAC circuitry 270 converts the digital signal x/VSupply into an equivalent analog signal and outputs this analog representation of the digital signal x/VSupply to the second input of the subtractor circuitry 220.

The subtractor circuitry 220 in this example is configured to subtract an output signal y generated by the analog output stage circuitry 210 from the analog representation of the digital signal x/VSupply output by the digital divider circuitry 260, to generate an error signal e, which is output to the analog loop filter circuitry 230.

The analog loop filter circuitry 230 is configured to filter the error signal e and to output a filtered version of the error signal e to the analog output stage circuitry 210, which is configured to generate the output signal y by modulating the supply voltage VSupply based on the filtered version of the error signal e output by the analog loop filter circuitry 230.

In the amplifier circuitry 200 of FIG. 2, any variation in the supply voltage VSupply is applied to the input signal x by the digital divider circuitry 260, such that the loop filter circuitry 230 is able to compensate for such supply voltage variation, thus reducing distortion in the output signal y.

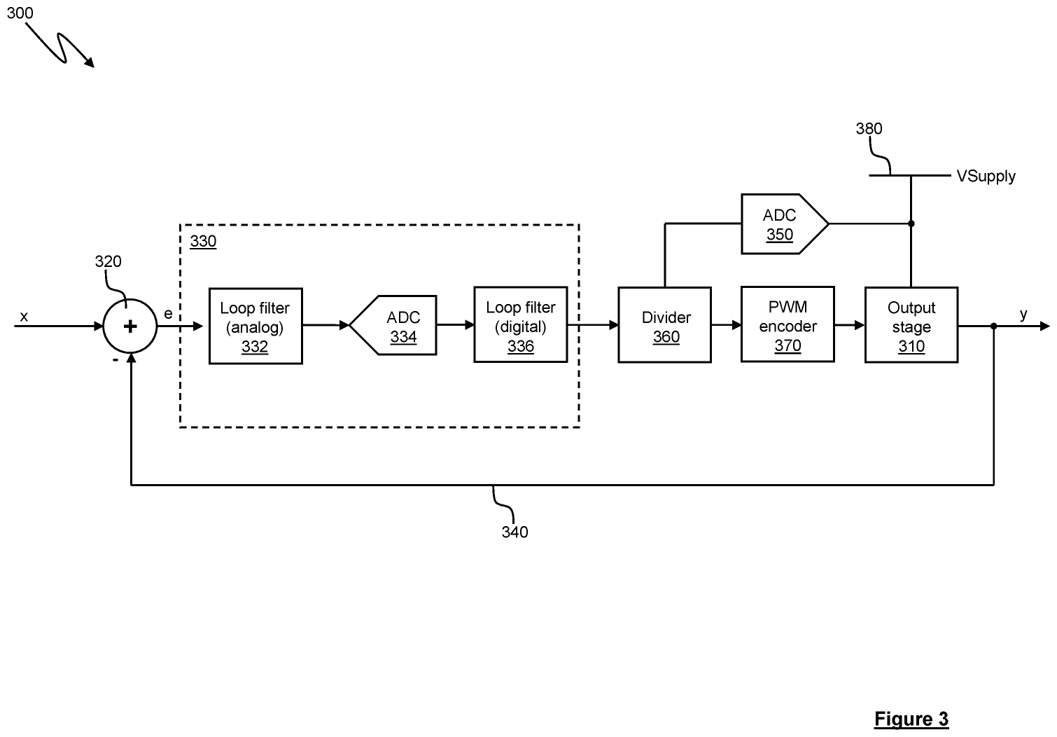

FIG. 3 is a schematic representation of amplifier circuitry with a loop filter arrangement and power supply compensation circuitry in accordance with the present disclosure.

The amplifier circuitry, shown generally at 300 in FIG. 3, includes analog output stage circuitry 310, subtractor circuitry 320, hybrid (analog-digital) loop filter circuitry 330 and an analog feedback path 340 that couples an output of the analog output stage circuitry 310 to a first input of the subtractor circuitry 320.

The amplifier circuitry 300 further includes analog to digital converter (ADC) circuitry 350, digital divider circuitry 360 and digital linear encoder circuitry 370.

The analog output stage circuitry 310, which may be, for example, Class D output stage circuitry, is configured to generate an output signal y by modulating a supply voltage VSupply based on a pulse width modulated signal output by the digital linear encoder circuitry 370.

The output signal y is fed back to the first input of the subtractor circuitry 320 by the analog feedback path 340. A second input of the subtractor circuitry 320 receives an input signal x, to be amplified by the amplifier circuitry 300. The input signal x may be, for example, a digital or analog audio signal. The subtractor circuitry 320 is configured to subtract the output signal y from the input signal x to generate an error signal e, which is output to the hybrid loop filter circuitry 330.

The hybrid loop filter circuitry 330 is configured to receive an analog input signal and to output a digital loop filter output signal. The feedback path 340, subtractor circuitry 320 and hybrid loop filter circuitry 330 thus form a feedback loop of the amplifier circuitry 300.

In this example the hybrid loop filter circuitry 330 includes analog loop filter circuitry 332 having an input coupled to the output of the subtractor circuitry 320, and an output coupled to an input of loop filter ADC circuitry 334. An output of the loop filter ADC circuitry 334 is coupled to an input of digital loop filter circuitry 336, and an output of the digital loop filter circuitry 336 is coupled to an input of the digital divider circuitry 360.

The analog loop filter circuitry 322 is configured to receive the error signal e and to output an analog output signal which is filtered version of the error signal. The analog loop filter circuitry 322 may comprise, for example, one or more analog integrators.

The loop filter ADC circuitry 334 is configured to receive the analog signal output by the analog loop filter circuitry 332, and to output a digital version of that signal to the digital loop filter circuitry 336.

The digital loop filter circuitry 336 is configured to perform a digital filtering operation on the received digital signal and to output a digital signal representing a filtered version of the error signal e to a first input of the digital divider circuitry 360. The digital loop filter circuitry 336 may comprise one or more digital integrators, for example.

In alternative examples, the analog loop filter circuitry 332 may be omitted, such that the error signal e output by the subtractor circuitry 320 is received by the loop filter ADC circuitry 334, and a digital signal representing the error signal e is output by the loop filter ADC circuitry 334 to the digital loop filter circuitry 336.

In further alternative examples, the digital loop filter circuitry 336 may be omitted, such that the digital version of the filtered error signal is output by the loop filter ADC circuitry 334 to the digital divider circuitry 360.

The hybrid loop filter circuitry 330 is thus configured to output a digitised filtered version of the error signal e to the divider circuitry 360.

An input of the ADC circuitry 350 is coupled to a positive power supply voltage rail 380 which provides the supply voltage VSupply to the analog output stage circuitry 310. An output of the ADC circuitry 350 is coupled to a second input of the digital divider circuitry 360, such that the ADC circuitry 350 supplies a digital signal representing a magnitude of the supply voltage VSupply to the digital divider circuitry 360.

The digital divider circuitry 360 is configured to divide the digital signal output by the hybrid loop filter circuitry 330 by the digital representation of the magnitude of the supply voltage VSupply output by the ADC circuitry 350 to generate a divided digital signal, which is output to the digital linear encoder circuitry 370.

The digital linear encoder circuitry 370 may be, for example, digital linear PWM encoder circuitry, and is configured to generate an encoded (e.g. PWM) output or drive signal for driving the analog output stage circuitry 310, based on the divided digital signal output by the digital divider circuitry 360. The digital linear encoder circuitry 370 thus outputs this encoded drive signal to the analog output stage circuitry 310.

Thus, in operation of the amplifier circuitry 300, the encoded (e.g. PWM) drive signal output by the digital linear encoder circuitry 370 to the output stage circuitry 310 is based on the divided digital signal output by the digital divider circuitry 360. The digital divider circuitry 360 applies a term 1/VSupply to the digitised filtered error signal that is input to the digital linear encoder circuitry 370, to compensate for any variations in the supply voltage VSupply that may otherwise affect the gain of the output stage circuitry 310.

The ADC circuitry 350, digital divider circuitry 360 and digital linear encoder circuitry 370 of FIG. 3 therefore act as power supply compensation circuitry, to compensate for the effect of variations in the supply voltage VSupply on the gain of the analog output stage circuitry 310.

Thus, in contrast to the amplifier circuitry 100 of FIG. 1, in the amplifier circuitry 300 of FIG. 3, the gain G of the analog output stage circuitry 310 is independent of the supply voltage VSupply, and can be expressed as G=k, where k is a constant.

In the amplifier circuitry 300 of FIG. 3, the 1/VSupply term is applied to the filtered error signal output by the hybrid loop filter circuitry 330. Thus, in contrast to the amplifier circuitry 200 of FIG. 2, in the amplifier circuitry 300 of FIG. 3, the loop filter circuitry 330 does not need to compensate for changes in the supply voltage VSupply. Instead, this compensation is performed by the ADC circuitry 350, digital divider circuitry 360 and digital linear encoder circuitry 370.

The use of the hybrid loop filter circuitry 330 in the amplifier circuitry 300 facilitates the use of the digital linear encoder circuitry 370, without requiring separate analog to digital converter circuitry between the hybrid loop filter circuitry 330 and the digital linear encoder circuitry 370.

As will be apparent from the foregoing discussion, the amplifier circuitry 300 is capable of compensating for supply-dependent variations in the gain of the output stage circuitry 310, by applying a 1/VSupply term to the digitised filtered version of the error signal that is output by the hybrid loop filter circuitry 330. As this 1/VSupply term is applied downstream of the hybrid loop filter 330, there is no need for the loop filter 330 to perform any compensation for such supply-dependent variations.

The sampling rate of the loop filer ADC circuitry 334 of the above-described hybrid loop filter circuitry 330 may be greater than an output rate of the circuitry in which the hybrid loop filter circuitry 330 is employed. For example, the sampling rate of the loop filter ADC circuitry 334 may be greater than an output rate of the digital linear encoder circuitry 370 in the amplifier circuitry 300 of FIG. 3.

The supply compensation arrangement described above with reference to FIG. 3 may be used in a variety of applications, e.g., in PWM-based Class D audio power amplifier circuitry, PWM based motor controller circuitry, PWM-based power converter circuitry (e.g., DC-DC converter circuitry), among other applications, and thus the present disclosure is not limited to any particular application of the circuitry.

The circuitry described above with reference to the accompanying drawings may be implemented as one or more integrated circuits (ICs), and/or may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD-or DVD-ROM, programmed memory such as read only memory (Firmware), or on a data carrier such as an optical or electrical signal carrier. For many applications, embodiments will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog™ or VHDL (Very high speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

1. Amplifier circuitry comprising:
output stage circuitry configured to modulate a power supply voltage, based on a drive signal received at an input of the output stage circuitry, to generate an amplifier output signal;
a feedback path coupled to an output of the output stage circuitry and configured to generate a feedback signal based on the amplifier output signal;
loop filter circuitry configured to receive an input signal based on the feedback signal and to output a digital loop filter output signal;
divider circuitry configured to divide the digital loop filter output signal by the power supply voltage to generate a divided digital output signal; and
encoder circuitry configured to generate the drive signal based on the divided digital output signal.

2. Amplifier circuitry according to claim 1, wherein the output stage circuitry comprises Class D output stage circuitry.

3. Amplifier circuitry according to claim 1, wherein the loop filter circuitry comprises analog to digital converter (ADC) circuitry.

4. Amplifier circuitry according to claim 3, wherein the loop filter circuitry comprises analog loop filter circuitry.

5. Amplifier circuitry according to claim 4, wherein the analog loop filter circuitry comprises one or more analog integrators.

6. Amplifier circuitry according to claim 3, wherein the loop filter circuitry comprises digital loop filter circuitry.

7. Amplifier circuitry according to claim 6, wherein the digital loop filter circuitry comprises digital integrator circuitry.

8. Amplifier circuitry according to claim 1, wherein the encoder circuitry comprises pulse width modulation (PWM) encoder circuitry.

9. Amplifier circuitry according to claim 1, wherein the input signal comprises an error signal indicative of a difference between an amplifier input signal and the amplifier output signal.

10. Amplifier circuitry according to claim 9, further comprising subtractor circuitry configured to subtract the amplifier output signal from the amplifier input signal.

11. Amplifier circuitry according to claim 9, wherein the amplifier input signal is an audio signal.

12. Amplifier circuitry comprising:
output stage circuitry configured to modulate a supply voltage to generate an amplifier output signal;
hybrid loop filter circuitry; and
compensation circuitry,
wherein the compensation circuitry is configured to generate a drive signal for driving the output stage circuitry based on an output signal of the hybrid loop filter circuitry,
wherein the drive signal is configured to compensate for a supply-dependent gain variation of the output stage circuitry.

13. Supply compensation circuitry comprising:
analog to digital converter (ADC) circuitry configured to generate a digital signal indicative of a supply voltage;
digital divider circuitry configured to divide an input signal by the digital signal indicative of the supply voltage to generate a divided digital signal; and
digital encoder circuitry configured to generate an encoded output signal based on the divided digital signal.

14. An integrated circuit comprising amplifier circuitry according to claim 1.

15. A host device comprising amplifier circuitry according to claim 1.

16. A host device according to claim 15, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.
